(19) United States
(12) Patent Application Publication
(10) Pub. No.: US 2013/0026437 A1
(43) Pub. Date: Jan. 31, 2013

(54) RESISTANCE VARIABLE MEMORY DEVICE AND METHOD FOR FABRICATING THE SAME

(71) Applicants: Seok-Pyo SONG, Gyeonggi-do (KR); Sung-Woong Chung, Gyeonggi-do (KR); Jae-Yun Yi, Gyeonggi-do (KR); Hye-Jung Choi, Gyeonggi-do (KR)

(72) Inventors: Seok-Pyo SONG, Gyeonggi-do (KR); Sung-Woong Chung, Gyeonggi-do (KR); Jae-Yun Yi, Gyeonggi-do (KR); Hye-Jung Choi, Gyeonggi-do (KR)

(21) Appl. No.: 13/338,443

(22) Filed: Dec. 28, 2011

(30) Foreign Application Priority Data
Jul. 29, 2011 (KR) 10-2011-0075950

(51) Int. Cl. H01L 45/00; H01L 21/8239

(52) U.S. Cl. 257/4; 438/382; 257/E21.645; 257/E21.004; 257/E45.001

(57) ABSTRACT

A method for fabricating a resistance variable memory device, includes: providing a substrate having first contacts and second contacts, where the second contacts do not overlap the first contacts; forming a line pattern over the substrate, the line pattern overlapping a first line and including a stacked structure of a first electrode, a resistor, and a second electrode; forming a first contact hole to expose the second contact; forming an insulating spacer on a sidewall of the first contact hole; forming a third contact to fill the first contact hole having the insulating spacer formed therein; and forming a third electrode over the third contact such that the third electrode overlaps a second line extending in a second direction and is cut open over the first contact, where the first and second contacts are alternately arranged on the second line.

### CROSS-REFERENCE TO RELATED APPLICATIONS

The present application claims priority of Korean Patent Application No. 10-2011-0075950, filed on Jul. 29, 2011, which is incorporated herein by reference in its entirety.

### BACKGROUND

1. Field

Exemplary embodiments of the present invention relate to a resistance variable memory device and a method for fabricating the same.

2. Description of the Related Art

A resistance variable memory device refers to a memory device which stores data, based on such a characteristic that resistors have different resistance states depending on an applied bias. Here, the resistors may include a transition metal oxide or perovskite-based material.

Such a resistance variable memory device may have a so-call crossbar array structure to increase the integration degree.

The crossbar array structure refers to a structure that includes a plurality of lower interconnections extending in parallel to each other, a plurality of upper interconnections crossing the lower interconnections and extending in parallel to each other, and a resistor disposed as a memory cell at each intersection between the upper and lower interconnections.

However, when such a crossbar array structure is used, a leakage current to an unselected memory cell may occur. In this case, an error may occur in storing and reading data of the resistance variable memory device, and power consumption may increase.

### SUMMARY

An embodiment of the present invention is directed to a resistance variable memory device capable of reducing a leakage current in comparison with a crossbar array structure and a method for fabricating the same.

In accordance with an embodiment of the present invention, a method for fabricating a resistance variable memory device, includes: providing a substrate having a plurality of first contacts and a plurality of second contacts, wherein the second contacts are arranged so as not to overlap the first contacts; forming a line pattern over the substrate, the line pattern overlapping a first line extending in a first direction and including a stacked structure of a first electrode, a resistor, and a second electrode, wherein the first and second contacts are alternately arranged on the first line; forming a first contact hole to expose the second contact by cutting open the line pattern; forming an insulating spacer on a sidewall of the first contact hole; forming a third contact to fill the first contact hole having the insulating spacer formed therein; and forming a third electrode over the third contact such that the third electrode overlaps a second line extending in a second direction crossing the first direction and is cut open over the first contact, wherein the first and second contacts are alternately arranged on the second line.

In accordance with another embodiment of the present invention, a resistance variable memory device includes: a substrate having a plurality of first contacts and a plurality of second contacts, wherein the second contacts are arranged so as not to overlap the first contacts; a first electrode disposed over the substrate and cut open over the second contact while overlapping a first line extending in a first direction, wherein the first and second contacts are alternately arranged on the first line; a third contact disposed over the second contact; an insulating spacer surrounding a sidewall of the third contact; a third electrode disposed over the third contact and cut open over the first contact while overlapping a second line extending in a second direction crossing the first direction, wherein the first and second contacts are alternately arranged on the second line; and a stacked structure of a resistor and a second electrode, wherein the stacked structure is disposed between the first and third electrodes.

### BRIEF DESCRIPTION OF THE DRAWINGS

FIGS. 1A and 1B to 4A and 4B illustrate a method for fabricating a resistance variable memory device in accordance with a first embodiment of the present invention.

FIGS. 5A and 5B to 9A and 9B illustrate the method for fabricating a resistance variable memory device in accordance with the second embodiment of the present invention.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

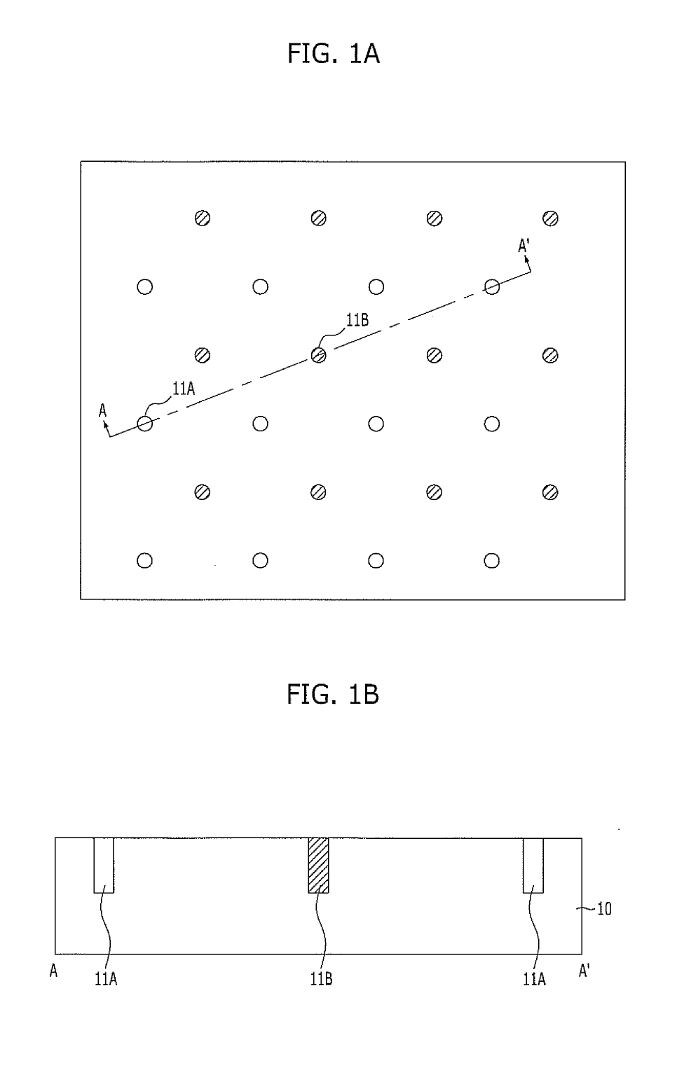

FIGS. 1A and 1B to 4A and 4B illustrate a method for fabricating a resistance variable memory device in accordance with a first embodiment of the present invention. FIGS. 1A to 4A are plan views, and FIGS. 1B to 4B are cross-sectional views taken along lines A-A′ of FIGS. 1A to 4A, respectively.

Referring to FIGS. 1A and 1B, a substrate 10 is provided. The substrate 10 includes a plurality of first and second contacts 11A and 11B to be coupled to a lower electrode and a second upper electrode which will be described below, while having a required predetermined lower structure which is not illustrated.

The first contacts 11A may be arranged in a matrix type along widthwise and lengthwise directions. The second contacts 11B may be arranged in a matrix type along widthwise and lengthwise directions so as to miss the first contacts 11A, while spaced apart from the first contacts 11A. However, the embodiment of the present invention is not limited to the structure, but the first and second contacts 11A and 11B may be regularly arranged while formed at different positions. The widths of the first and second contacts 11A and 11B may be controlled to be small in order to prevent the first and second contacts 11A and 11B from being shorted to the second upper electrode or the lower electrode.

The first and second contacts 11A and 11B may be coupled to transistors or interconnections formed in the substrates 10 and controlled by the transistors or interconnections which are not illustrated. However, the detailed descriptions thereof will be omitted. Furthermore, in this embodiment, the first and second contacts 11A and 11B may be arranged in such a manner that the lower surfaces thereof are set to different heights to couple to a lower structure and the upper surfaces thereof are set to the same height. When the upper surfaces of the first and second contacts 11A and 11B are positioned at the same height, a subsequent bar-type pattern formation process and third contact formation process may be easily performed.

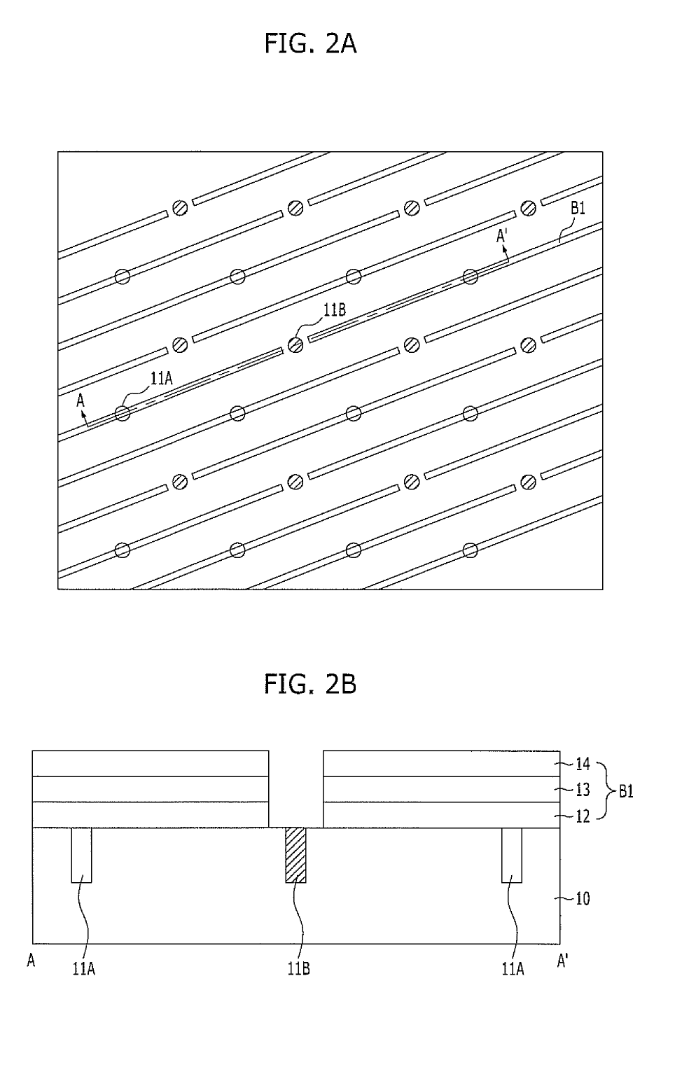

Referring to FIGS. 2A and 2B, when it is assumed that a plurality of first virtual lines extend in one direction and the first and second contacts 11A and 11B are alternately arranged on each of the first virtual lines, a plurality of first bar-type patterns B1 are formed. Each of the first bar-type patterns B1 is extended along the first virtual line and cut over the second contacts 11B, thereby exposing the second contacts 11B.

That is, each of the first bar-type pattern B1 having the major axis along the first virtual line overlaps the first contacts 11A, but does not overlap the second contacts 11B on either side of the first contact 11A. At this time, the length of the major axis of the first bar-type pattern B1 is small enough to prevent the first bar-type pattern B1 and the second contacts 11B from being shorted to each other while the length is sufficiently large to form many resistors. Here, the length may be properly controlled to satisfy both conditions.

In this embodiment, the first virtual line is extended in the same direction as the line A-A′. Without being limited thereto, however, the extension direction of the first virtual line may be changed as long as the first and second contacts 11A and 11B are alternately arranged on the first virtual line.

The first bar-type pattern B1 has a multilayer structure in which a lower electrode 12, a resistor pattern 13, and a first upper electrode pattern 14 are sequentially stacked. The first bar-type pattern B1 may be formed by sequentially depositing a conductive layer for forming the lower electrode 12, a material layer for forming the resistor pattern 13, and a conductive layer for forming the first upper electrode pattern 14 over the substrate 10 and then patterning the stacked layers through a mask and etching process. The material layer may include a transition metal oxide layer or perovskite-based material layer. This patterning process may be precisely controlled to form the bar-type pattern B1 which satisfies the above-described arrangement relation.

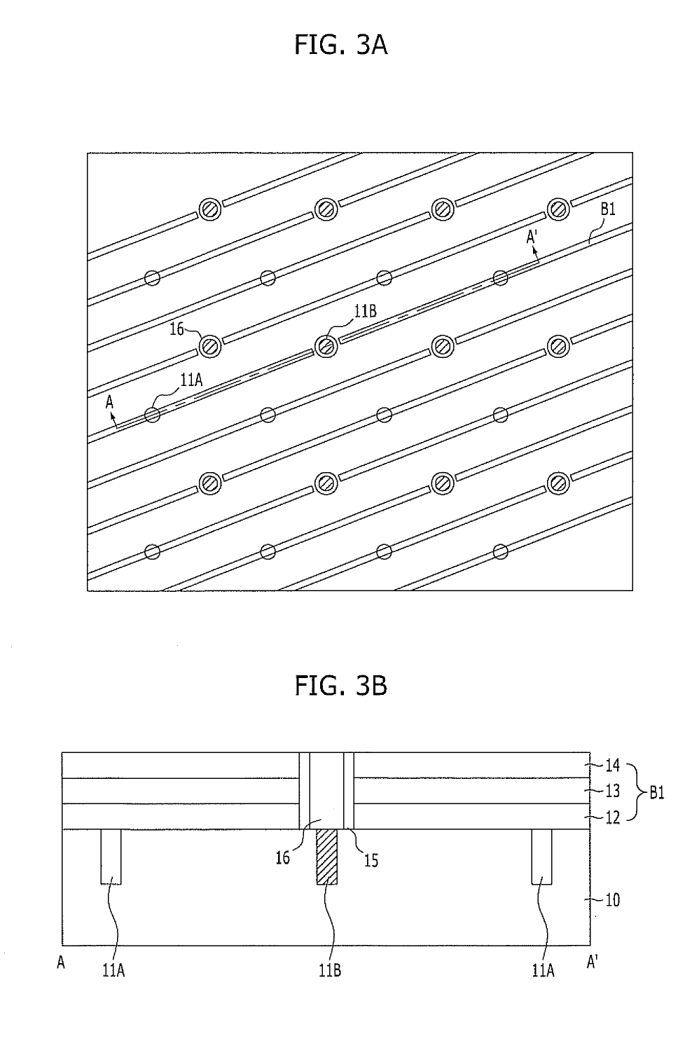

Referring to FIGS. 3A and 3B, an insulation layer 15 is formed to fill the space between the first bar-type patterns over the substrate 10.

At this time, the insulation layer 15 may be formed by depositing an insulation material covering the substrate 10 having the first-bar type pattern B1 formed thereon, for example, an oxide layer and performing a planarization process, for example, an etch-back process or chemical mechanical polishing (CMP) process until the first upper electrode pattern 14 is exposed.

Subsequently, a contact hole is formed in the insulation layer 15 by a mask and etching process to expose the second contact 11B, and a conductive material is buried in the contact hole to form a third contact 16 which is electrically coupled to the second contact 11B. In the mask and etching process, the position and width of the third contact 16 may be precisely controlled to substantially prevent the third contact 16 and the first bar-type pattern B1 from being shorted.

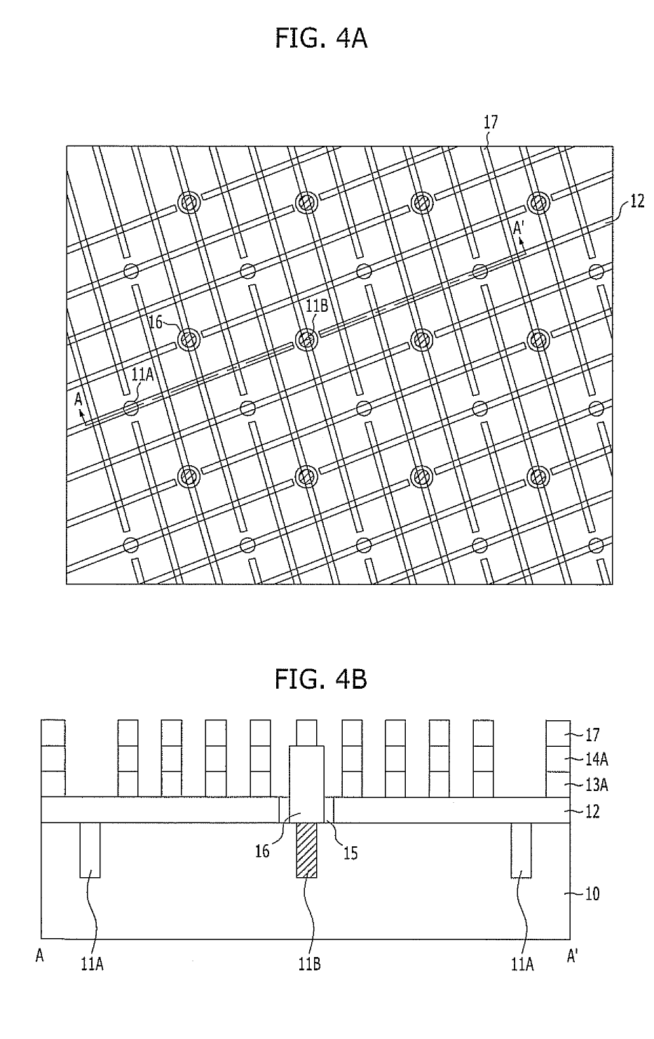

Referring to FIGS. 4A and 4B, when it is assumed that a plurality of second virtual lines are extended in a direction crossing the first virtual lines and the first and second contacts 11A and 11B are alternately arranged on each of the second virtual lines, a plurality of bar-type second upper electrodes 17 are formed on the resultant structure as shown in FIGS. 4A and 4B. Each of the bar-type second upper electrode 17 is extended along the second virtual line and skips over the first contacts 11A, thereby exposing the lower electrode 12 in regions overlapped by the first contacts 11A. Then, the first upper electrode pattern 14 and the resistor pattern 13 exposed by the second upper electrode 17 are removed to form a first upper electrode 14A and a resistor 13A.

That is, the second upper electrode 17 has the major axis on the second virtual line, and overlaps the second contact 11B but does not overlap the first contacts 11A at either side of the second contact 11B. At this time, the length of the major axis of the second upper electrode 17 is small enough to prevent the second upper electrode 17 from being shorted to the lower electrode 12 through the first contact 11A and yet large enough to form many resistors. Here, the length may be properly controlled to satisfy both conditions. The stacked structure of the resistor 13A and the first upper electrode 14A has an isolated island shape, while disposed at each intersection between the lower electrodes 12 and the second upper electrodes 17.

The resistor 13A, the first upper electrode 14A, and the second upper electrode 17 may be formed by depositing a conductive layer for forming the second upper electrode 17 over the resultant structure of FIGS. 3A and 3B and patterning the conductive layer, the first upper electrode pattern 14, and the resistor pattern 13 through a mask and etching process. This patterning process may be precisely controlled as in the first bar-type pattern formation process.

By using the above-described process, a resistance variable memory device that includes the substrate 10 which has the first and second contacts 11A and 11B, the lower electrode 12 which is extended along the first virtual line while the lower electrode 12 is coupled to the first contacts 11A over the substrate 10 and is cut at each region where the second contact 11B is positioned, the second upper electrode 17 which extends along the second virtual line and is coupled to the second contact 11B through the third contact 16 and is removed at each region where the first contact 11A is positioned, and the stacked structure of the resistor 13A and the first upper electrode 14A which are interposed between the lower electrode 12 and the second upper electrode 17.

In the resistance variable memory device in accordance with the embodiment of the present invention, the resistor 13A is disposed at each intersection between the upper and lower electrodes 12 and 17, similar to the conventional crossbar array structure, where such a structure may increase the integration degree. Furthermore, since the resistance variable memory device includes the lower electrode 12 and the second upper electrode 17 having cut-open portions, the number of leakage current paths to unselected memory cells may be significantly reduced.

Hereafter, a method for fabricating a resistance variable memory device in accordance with a second embodiment of the present invention will be described. The method for fabricating a resistance variable memory device in accordance with the second embodiment of the present invention is performed in a similar manner to the method in accordance with the first embodiment of the present invention, but may be more easily performed than the first embodiment of the present invention.

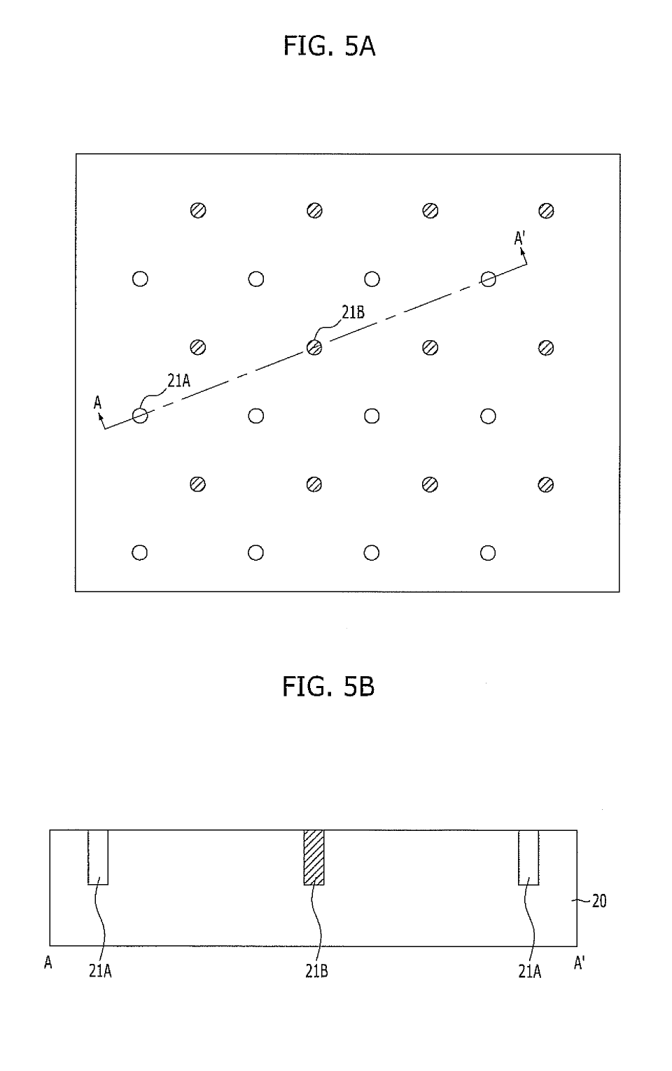

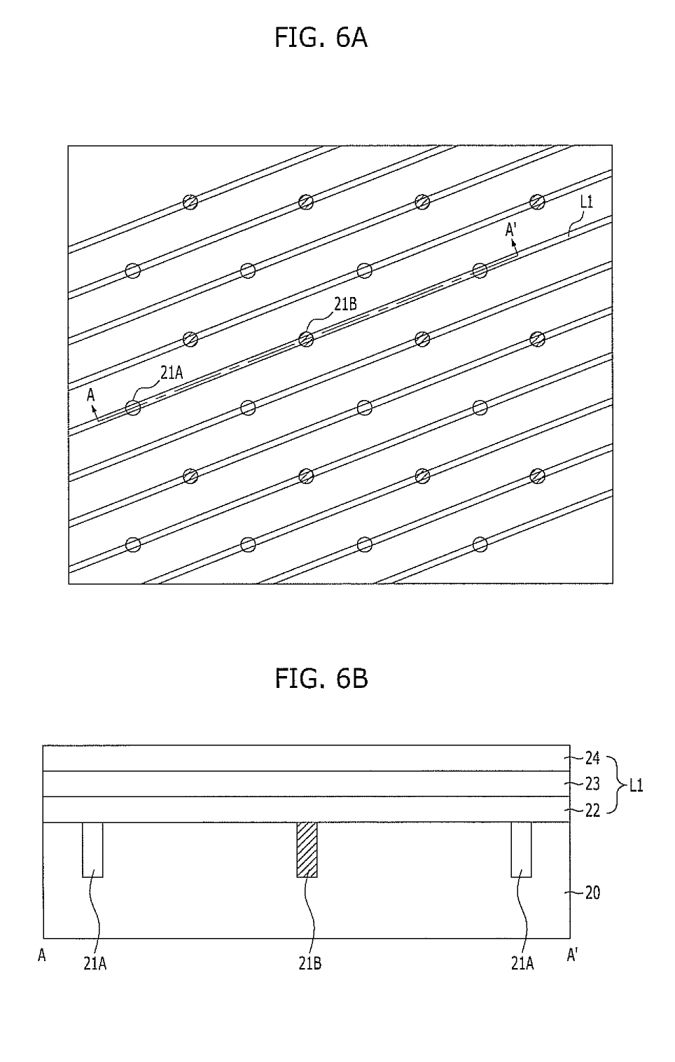

FIGS. 5A and 5B to 9A and 9B illustrate the method for fabricating a resistance variable memory device in accordance with the second embodiment of the present invention. FIGS. 5A to 9A are plan views, and FIGS. 6B to 9B are cross-sectional views.

Referring to FIGS. 5A and 5B, a substrate 20 is provided. The substrate 20 includes a plurality of first and second contacts 21A and 21B to be coupled to a lower electrode and a second upper electrode which will be described below, while having a lower structure (not shown).

The substrate 20 substantially has the same structure as the substrate 10 in accordance with the first embodiment of the present invention, and thus the detailed descriptions thereof are omitted herein.

Referring to FIGS. 6A and 6B, when it is assumed that a plurality of first virtual lines extend in one direction and the first and second contacts 21A and 21B are alternately arranged on each of the first virtual lines, a first line pattern L1 is formed on the substrate 20 so as to extend along the first virtual line. That is, the first line pattern L1 is formed on the substrate 20 so as to overlap both of the first and second contacts 21A and 21B.

The first line pattern L1 has a multilayer structure in which a lower electrode pattern 22, a primary resistor pattern 23, and a primary first-upper-electrode pattern 24 are sequentially stacked. The first line pattern L1 may be formed by sequentially depositing a conductive layer for forming a lower electrode, a material layer for forming a resistor, and a conductive layer for forming a first upper electrode over the substrate 20 and subsequently patterning the deposited layers through a mask and etching process. The material layer may include a transition metal layer or perovskite-based material layer.

Although not illustrated in the drawings, an insulation layer is formed to fill the space between the first line patterns L1 over the substrate 20. The insulation layer may be formed by depositing an insulation material covering the substrate 20 having the first line pattern L1 formed therein, for example, an oxide layer and subsequently planarizing the insulation material until the primary first-upper-electrode pattern 24 is exposed.

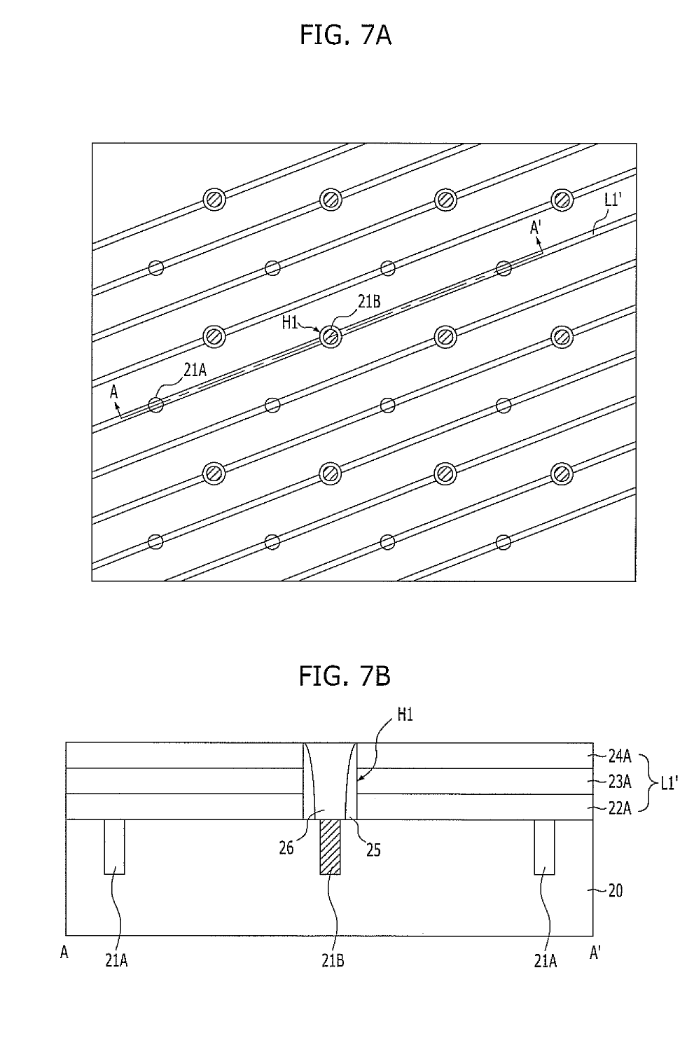

Referring to FIGS. 7A and 7B, a first contact hole H1 is formed by a mask and etching process. The first contact hole H1 passes through the first line pattern L1 while cutting the first line pattern L1 and exposes the second contact 21B.

The first line pattern L1 on the first virtual line is cut over the second contact 21B by the first line contact hole H1, and hereafter referred to as the cut first line pattern L1′. The cut first line pattern L1′ has a multilayer structure in which a lower electrode 22A, a secondary resistor pattern 23A, and a secondary first-upper-electrode pattern 24A are sequentially stacked. At this time, the first contact hole H1 may have a width equal to or more than the line width of the first line pattern L1 and the width of the second contact 21B.

Subsequently, an insulating spacer 25 is formed on the sidewall of the first contact hole H1, and a third contact 26 is subsequently formed to fill the first contact hole H1 having the insulating spacer formed therein.

The insulating spacer 25 may be formed by depositing an insulation layer, for example, a nitride layer along the entire surface of the resultant structure including the first contact hole H1 and then etching the nitride layer through a blanket process. Due to the characteristic of the blanket process, the insulating spacer 25 has a shape of which the width gradually decreases from the lower portion toward the upper portion thereof.

The third contact 26 may be formed by depositing a conductive material to such a thickness as to sufficiently fill the first contact hole H1 having the insulating spacer 25 formed therein and subsequently performing a planarization process until the secondary first-upper-electrode pattern 24A is exposed. Since the third contact 26 fills the space where the insulating spacer 25 is formed, the third contact 26 has a shape where the width thereof gradually increases from the lower portion toward the upper portion thereof along the boundary of the insulating spacer 25.

Through the above-described process of FIGS. 6A, 6B, 7A, and 7B, the cut first line pattern L1′ and the third contact 26 which are similar to the first bar-type pattern B1 and the third contact 16 in accordance with the first embodiment may be formed. Here, the process in accordance with the second embodiment of the present invention is easier than the process in accordance with the first embodiment of the present invention (refer to FIGS. 2A, 2B, 3A, and 3B).

In the first embodiment of the present invention, the patterning process should be precisely controlled. That is, the first bar-type pattern B1 is to be patterned so as not to have a short connection to the second contact 11B, and the contact hole for forming the third contact 16 is to be patterned so as not to have a short connection to any one of the first bar-type pattern B1 through areas between the first bar-type patterns B1. On the other hand, in the process in accordance with the second embodiment of the present invention, the first line pattern L1 having a simple line shape is formed and then cut during the process for forming the contact hole H1. Therefore, patterning does not need to be precisely controlled, and thus the process may be easily performed.

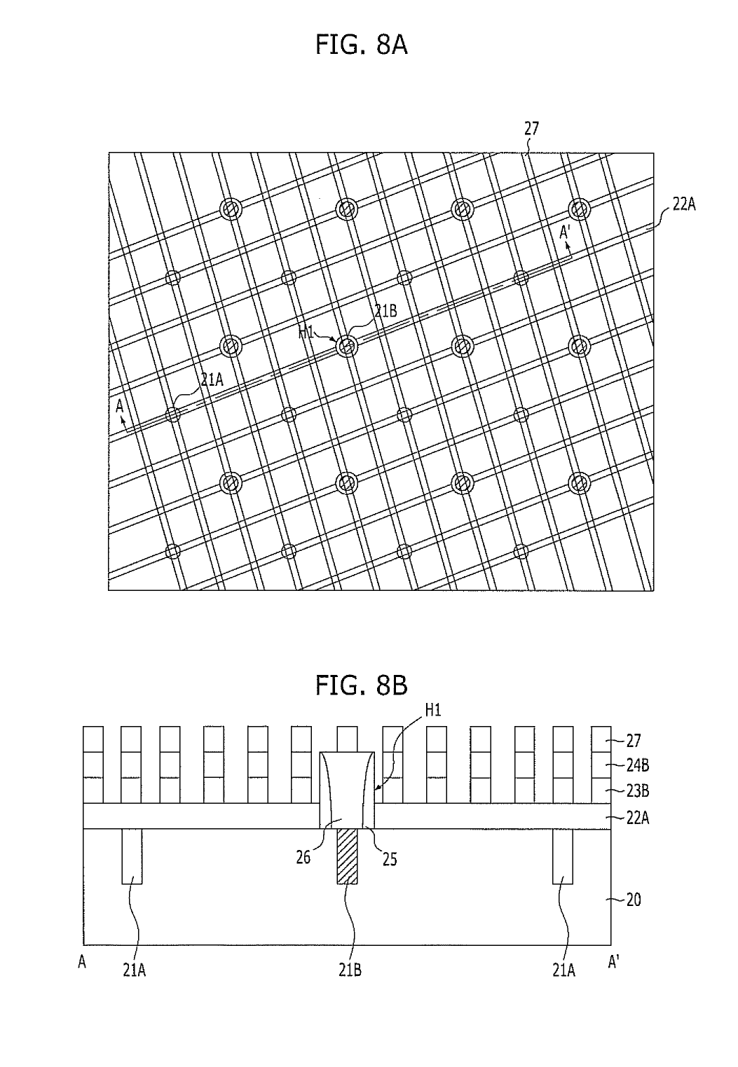

Referring to FIGS. 8A and 8B, when it is assumed that a plurality of second virtual lines extend in a direction crossing the first virtual line and the first and second contacts 21A and 21B are alternately arranged on each of the second virtual lines, a second upper electrode pattern 27 having a line type extending along the second virtual line is formed over the resultant structure of FIGS. 7A and 7B, and the secondary first-upper-electrode pattern 24A and the secondary resistor pattern 23A exposed by the second upper electrode pattern 27 are removed to form a first upper electrode 24B and a resistor 23B.

That is, the second upper electrode pattern 27 extends to overlap both of the first and second contacts 21A and 21B on the second virtual line. The stacked structure of the resistor 23B and the first upper electrode 24B has an isolated island shape, while disposed at each intersection between the lower electrode 22A and the second upper electrode pattern 27.

The resistor 23B, the first upper electrode 24B, and the second upper electrode pattern 27 may be formed by depositing a conductive layer for forming a conductive layer for the second upper electrode on the resultant structure of FIGS. 7A and 7B and subsequently patterning the conductive layer, the secondary first-upper-electrode pattern 24A, and the secondary resistor pattern 23A through a mask and etching process.

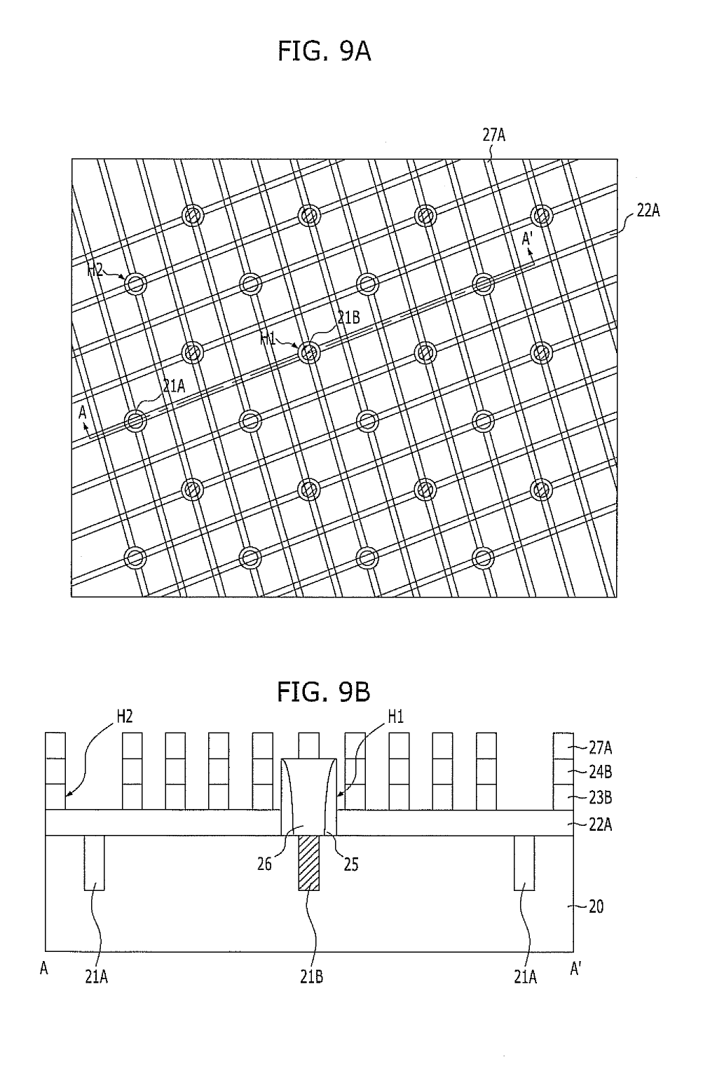

Referring to FIGS. 9A and 9B, a second contact hole H2 is formed by a mask and etching process. The second contact hole H2 passes through the second upper electrode pattern 27 and exposes the lower electrode 22A over the first contact 21A by cutting open the corresponding regions of the second upper electrode pattern 27. During the formation process of the second contact hole H2, the resistor 23B and the first upper electrode 24B existing under the second upper electrode pattern 27 are removed together.

The second upper electrode pattern 27 on the second virtual line is cut open over the first contact 21A by the second contact hole H2, and hereafter referred to as a second upper electrode 27A. The second contact hole H2 may have a width equal to or more than the line width of the second upper electrode 27A and the width of the first contact 21A.

Through the above-described process of FIGS. 8A, 8B, 9A, and 9B, the second upper electrode 27A similar to the bar-type second upper electrode 17 in accordance with the first embodiment of the present invention may be formed. However, the formation process of the second upper electrode 27A is easier than the formation process of the second upper electrode 17 in accordance with the first embodiment of the present invention. In the first embodiment of the present invention, the patterning process may be precisely performed in such a manner that the second upper electrode 17 is not short-connected to the first contact 11A. On the other hand, in the process in accordance with the second embodiment of the present invention, the second upper electrode pattern 17 having a simple line shape is formed first, and subsequently cut open during the formation process of the contact hole H2. Therefore, patterning does not need to be precisely performed, and the process is easily performed.

The device fabricated as the result of the process in accordance with the second embodiment of the present invention will be described with reference to FIGS. 9A and 9B.

The resistance variable memory device in accordance with the second embodiment of the present invention includes the substrate 20 which has the plurality of first contacts 21A and the plurality of second contacts 21B arranged so as not to overlap the first contacts 21A, the lower electrode 22A which is disposed over the substrate 20, is cut open over the second contacts 21B while overlapping the first virtual line extending in a first direction, and exposes the second contacts 21B, the third contact 26 which is disposed over the exposed second contact 21B, the insulating spacer 25 which is formed on the sidewall of the third contact 26 to insulate the lower electrode 22A from the third contact 26, the second upper electrode 27A which is disposed over the third contact 26 and cut open over the first contact 21A while overlapping the second virtual line extended in a second direction crossing the first direction, and the stacked structure of the resistor 23B and the first upper electrode 24B, which is disposed at each intersection between the upper electrode 22A and the second upper electrode 27A and has an island shape.

Here, since the insulating spacer 25 is formed through the series of process including the formation of the contact hole H1, the deposition of the insulation material, and the blanket process, the insulating spacer 25 has a shape where the width thereof gradually decreases from the lower portion toward the upper portion thereof. Accordingly, the third contact 26 has a shape where its width gradually increase from the lower portion toward the upper portion thereof.

In accordance with the embodiment of the present invention, the structure capable of reducing a leakage current instead of the crossbar array structure may be proposed, and the method for fabricating the structure may be easily performed.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a resistance variable memory device, comprising:
providing a substrate having a plurality of first contacts and a plurality of second contacts, wherein the second contacts are arranged so as not to overlap the first contacts;
forming a line pattern over the substrate, the line pattern overlapping a first line extending in a first direction and comprising a stacked structure of a first electrode, a resistor, and a second electrode, wherein the first and second contacts are alternately arranged on the first line;
forming a first contact hole to expose the second contact by cutting open the line pattern;
forming an insulating spacer on a sidewall of the first contact hole;
forming a third contact to fill the first contact hole having the insulating spacer formed therein; and
forming a third electrode over the third contact such that the third electrode overlaps a second line extending in a second direction crossing the first direction and is cut open over the first contact, wherein the first and second contacts are alternately arranged on the second line.

2. The method of claim 1, wherein, in the forming of the third electrode, the second electrode and the resistor exposed by the third electrode are removed.

3. The method of claim 1, wherein the forming of the third electrode comprises:
forming a third electrode pattern to overlap the second line and removing the second electrode and the resistor exposed by the third electrode pattern; and
forming a second contact hole to expose the first electrode overlapping the first contact by cutting open corresponding regions of the third electrode pattern.

4. The method of claim 1, wherein the first contacts are arranged along a line that is arranged to not contact the second contacts.

5. The method of claim 1, wherein the first contacts are arranged along a third direction and a fourth direction crossing the third direction,
the second contacts are arranged along the third direction and the fourth direction, while missing the first contacts,
the first to fourth directions do not coincide with one another.

6. The method of claim 1, wherein the width of the first contact hole is equal to or greater than a width of the second contacts.

7. The method of claim 1, wherein the width of the first contact hole is equal to or greater than a line width of the line pattern.

8. The method of claim 3, wherein the width of the second contact hole is equal to or greater than a width of the first contact.

9. The method of claim 3, wherein the width of the second contact hole is equal to or greater than a line width of the line pattern.

10. The method of claim 1, wherein upper surfaces of the first and second contacts are at the same height.

11. A resistance variable memory device comprising:
a substrate having a plurality of first contacts and a plurality of second contacts, wherein the second contacts are arranged so as not to overlap the first contacts;
a first electrode disposed over the substrate and cut open over the second contact while overlapping a first line extending in a first direction, wherein the first and second contacts are alternately arranged on the first line;
a third contact disposed over the second contact;
an insulating spacer surrounding a sidewall of the third contact;
a third electrode disposed over the third contact and cut open over the first contact while overlapping a second line extending in a second direction crossing the first direction, wherein the first and second contacts are alternately arranged on the second line; and
a stacked structure of a resistor and a second electrode, wherein the stacked structure is disposed between the first and third electrodes.

12. The resistance variable memory device of claim 11, wherein the third contact has a width that increases as the third contact extends from a lower portion toward an upper portion thereof, and
the insulating spacer has a width that decreases as the insulating spacer extends from a lower portion toward an upper portion thereof.

13. The resistance variable memory device of claim 11, wherein upper surfaces of the first and second contacts are at the same height.

14. The resistance variable memory device of claim 11, wherein the first contacts are arranged along a line that is arranged to not contact the second contacts.

15. The method of claim 11, wherein the first contacts are arranged along a third direction and a fourth direction crossing the third direction,
the second contacts are arranged along the third direction and the fourth direction, while missing the first contacts,
the first to fourth directions do not coincide with one another.

16. The resistance variable memory device of claim 11, wherein the width of the third contact is equal to or greater than a width of the second contacts.

17. The resistance variable memory device of claim 11, wherein the width of the third contact is equal to or greater than a line width of the line pattern.

18. The resistance variable memory device of claim 11, wherein one or more of the third electrode are disposed between one of the first contacts and second contact adjacent to the one of the first contacts over the first line.

19. The resistance variable memory device of claim 18, wherein the stacked structure is disposed at each intersection between the first electrode and the third electrode.
